(19) United States
(12) Patent Application Publication
(10) Pub. No.: US 2014/0048208 A1
(43) Pub. Date: Feb. 20, 2014

(54) APPARATUS FOR FABRICATING SEMICONDUCTOR DEVICES

(71) Applicant: SAMSUNG ELECTRONICS CO., LTD., Suwon-Si (KR)

(72) Inventor: Ki-Seok KIM, Osan-si (KR)

(73) Assignee: SAMSUNG ELECTRONICS CO., LTD., Suwon-Si (KR)

(21) Appl. No.: 13/905,825

(22) Filed: May 30, 2013

(30) Foreign Application Priority Data
Aug. 17, 2012 (KR) 10-2012-0090300

(51) Int. Cl. H01L 21/02

(52) U.S. Cl. CPC H01L 21/02057
USPC 156/345.31

(57) ABSTRACT

An apparatus for fabricating semiconductor devices including a load-lock part arranged adjacent to a front side of a transfer part, a cleaning part and at least two process chambers arranged side by side adjacent to a back side of the transfer part, a plasma supply module arranged at a back side of the cleaning part and configured to supply plasma to the cleaning part, and a reaction gas exhaust part coupled to the cleaning part and arranged below the transfer part and configured to exhaust a reaction gas from the cleaning part may be provided.

### CROSS-REFERENCE TO RELATED APPLICATION

This application claims priority under 35 U.S.C. §119 to Korean Patent Application No. 10-2012-0090300 filed on Aug. 17, 2012, the disclosure of which is hereby incorporated by reference in its entirety.

### BACKGROUND

1. Field

Example embodiments relate to an apparatus for fabricating semiconductor devices and a method of manufacturing a semiconductor device using the same.

2. Description of Related Art

As semiconductor devices have become more and more highly integrated, a tolerance level for defects generated during a manufacturing process is being managed very strictly.

### SUMMARY

Some example embodiments provide an apparatus of fabricating semiconductor devices.

Other example embodiments provide a cluster-type apparatus of fabricating semiconductor devices having multiple functions.

Still other example embodiments provide an apparatus for fabricating semiconductor devices, which can perform multiple processes in-situ without breaking vacuum.

Yet other example embodiments provide an apparatus for fabricating semiconductor devices, which can perform a cleaning process and a growing process, continuously.

Yet other example embodiments provide a method of manufacturing a semiconductor device using the aforementioned apparatus.

Example embodiments are not limited to the above disclosure; other embodiments may become apparent to those of ordinary skill in the art based on the following descriptions.

According to an example embodiment, an apparatus for fabricating semiconductor devices includes a load-lock part arranged adjacent to a front side of a transfer part, a cleaning part and at least two process chambers arranged side-by-side adjacent to a back side of the transfer part, a plasma supply module arranged at a back side of the cleaning part to face the transfer part and configured to supply plasma to the cleaning part, and a reaction gas exhaust part arranged below the transfer part to be coupled to the cleaning part and configured to exhaust a reaction gas from the cleaning part.

According to another example embodiment, an apparatus for fabricating semiconductor devices includes a load-lock chamber arranged at a front side of a transfer chamber, a stock table arranged at a front side of the load-lock chamber, a cleaning part and a process chamber arranged at a back side of the transfer chamber, wherein the cleaning part includes a load/unload chamber at an upper part and a cleaning chamber at a lower part, a plasma supply module arranged at a back side of the cleaning chamber, first and second plasma supply pipes configured to supply plasma from the plasma supply module to the cleaning chamber, and a reaction gas exhaust part arranged at a front side of the cleaning part. The first plasma supply pipe supplies the plasma to an upper part of the cleaning chamber, and the second plasma supply pipe supplies the plasma to a lower part of the cleaning chamber.

According to still another example embodiment, a semiconductor processing apparatus includes a cleaning part and at least one processing part arranged side-by-side at a back side of a transfer part, plasma supply elements coupled to the cleaning part at a back side of the cleaning part, and a reaction gas exhaust part coupled to the cleaning part at a front side of the cleaning part. The reaction gas exhaust part is vertically at a different level from the transfer part and configured to exhaust a reaction gas.

The transfer part may overlap the reaction gas exhaust in a plan view.

The semiconductor processing apparatus of claim 16, wherein the plasma supply elements are configured to be integrated into a module.

The semiconductor processing apparatus of claim 16 may further include a standby chamber. The standby chamber may be configured to temporarily store a processed semiconductor wafer from the cleaning part. The standby chamber may be configured to cool a processed semiconductor wafer from the at least one processing part

The cleaning part and the at least one processing part may be configured to perform processes in-situ. The cleaning part may be configured to at least partially remove a native oxide and the at least one processing part may be configured to perform processes other than removing a native oxide.

The aforementioned and other example embodiments will be appreciated from the following description, taken in conjunction with the accompanying drawings.

### BRIEF DESCRIPTION OF THE DRAWINGS

The foregoing and other features and advantages of the inventive concepts will become more apparent by describing in detail example embodiments with reference to the accompanying drawings. Like reference numerals in the drawings refer to like elements. The drawings are not necessarily to scale and may not precisely reflect the precise structural or performance characteristics of any given embodiment. Instead, emphasis may be placed on the drawings to illustrate the principles of the example embodiment. In the drawings:

FIGS. 1A and 1B are a top view and a side view schematically illustrating an apparatus for fabricating semiconductor devices in accordance with an example embodiment;

FIGS. 2A to 2C are block diagrams schematically illustrating plasma supply modules of the apparatus for fabricating semiconductor devices in accordance with example embodiments;

FIGS. 3A to 3F are block diagrams schematically illustrating various plasma generators of plasma supply modules in accordance with various example embodiments;

FIGS. 4A to 4C are block diagrams schematically illustrating a cleaning chamber of an apparatus for fabricating semiconductor devices in accordance with example embodiments;

FIGS. 5A to 5C are a perspective view, a cross-sectional perspective view, and a cross-sectional view, respectively, schematically illustrating a plasma supply pipe combined with a cleaning chamber;

FIG. 6 is a disassembled view schematically illustrating the cleaning chamber of an apparatus for fabricating semiconductor devices in accordance with an example embodiment;

FIG. 7 is a block diagram schematically illustrating an apparatus for fabricating semiconductor devices in accordance with an example embodiment; and

FIG. 8 is a flowchart describing processes of manufacturing a semiconductor device using an apparatus for fabricating semiconductor devices in accordance with an example embodiment.

### DETAILED DESCRIPTION

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

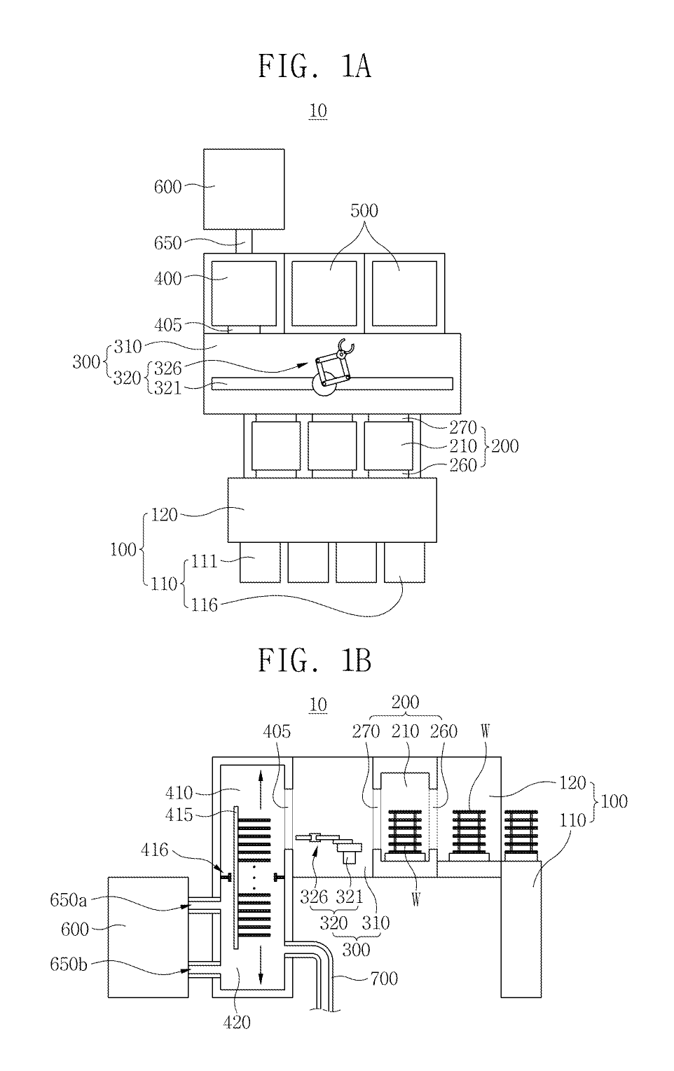

FIGS. 1A and 1B are a top view and a side view schematically illustrating an apparatus for fabricating semiconductor devices 10 in accordance with an example embodiment.

Referring to FIGS. 1A and 1B, the apparatus for fabricating semiconductor devices 10 in accordance with an example embodiment may include a stock part 100, a load-lock part 200, a transfer part 300, a cleaning part 400, process chambers 500, and a plasma supply module 600.

The stock part 100 may be located at the forefront of the apparatus for fabricating semiconductor devices 10. The stock part 100 may include stock tables 110 and a stock rack 120. Wafers W may be stocked on the stock tables 110. For example, one lot including plural wafers W may be stocked on the stock tables 110. The wafers W may be inserted and stacked in a wafer carrier or a wafer cassette.

The stock tables 110 may include at least one inlet stock table 111 and at least one outlet stock table 116. The inlet stock table 111 may be arranged near to the cleaning part 400 (e.g., at a side facing the cleaning part 400), and the outlet stock table 116 may be arranged near to the process chambers 500 (e.g., at a side facing the process chambers 500). The inlet stock table 111 and the outlet stock table 116 may be compatible.

The wafers on the inlet stock table 111 may temporarily stay at the stock rack 120 before to be assigned and input to the load-lock chambers 210. The wafers W on the outlet stock 116 may temporarily stay at the stock rack 120 after being withdrawn and output from the load-lock chambers 210. The stock tables 110 may have an elevating capability.

In some embodiments, the stock tables 110 or the stock rack 120 may be unified, assembled, or integrated as a single body or module. Alternatively, one of the stock tables 110 and the stock rack 120 may be omitted.

The load-lock part 200 may be arranged between the stock rack 120 and a transfer chamber 310. The load-lock part 200 may be arranged in a back side of the stock part 100. That is, the stock part 100 may be arranged in a front side of the load-lock part 200.

The load-lock part 200 may include a plurality of load-lock chambers 210, outer doors 260, and inner doors 270.

One load-lock chamber 210 may accommodate one set of wafers W. One set may be interpreted as the number of wafers W which one wafer carrier may hold. For example, one set of wafers W may be integer times of the number of one lot of wafers W. Generally, one lot of wafers W may be twenty-five wafers W.

The load-lock part 200 may include the outer doors 260 through which the insides of the load-lock chambers 210 is spatially connected to the stock part 100, and the inner doors 270 through which the insides of the load-lock chambers 210 is spatially connected to the transfer chamber 310. The internal pressures of the load-lock chambers 210 may be selectively adjusted to be the same as an external atmospheric pressure or an internal atmospheric pressure. For example, the load-lock part 200 may open the outer door 260 under the atmospheric pressure, then receive the wafers W from the stock part 100 into the load-lock chamber 210 through the outer door 260, then close the outer door 260 to seal the inside of the load-lock chamber 210, then evacuate the load-lock chamber 210 so that the internal pressure is adjusted to have the same pressure as the transfer chamber 310, then open the inner door 270, and then transfer the wafers W in the load-lock chamber 210 to the transfer chamber 310. Reversely, the load-lock part 200 may open the inner door 270 while the inside of the load-lock chamber 210 is in a vacuum state, then receive the wafers W from the transfer chamber 310 through the inner door 270, then close the inner door 270 to seal the inside of the load-lock chamber 210, then adjust the internal pressure of the load-lock chamber 210 to be an atmospheric pressure, then open the outer door 260, and then transfer the wafers W in the inside of the load-lock chamber 210 to the stock part 100.

The transfer part 300 may be arranged between the load-lock chambers 210 and the cleaning part 400, and between the load-lock part 200 and the process chambers 500. The transfer part 300 may be arranged in a back side of the load-lock part 200.

The transfer part 300 may include the transfer chamber 310 and a transfer module 320. The transfer module 320 may include a transfer rail 321 and a transfer arm 326. The transfer rail 321 may provide a track on which the transfer arm 326 moves.

The transfer arm 326 may supply or withdraw the wafers W to or from the load-lock part 200, the cleaning part 400, and the process chambers 500.

The transfer chamber 310 may supply or withdraw the wafers W to or from the cleaning part 400 and/or the process chambers 500 using the transfer module 320 while maintaining the vacuum state. For example, the transfer module 320 may unload the wafers W from the load-lock chambers 210 to load to the cleaning part 400.

The transfer module 320 may withdraw the wafers W from the cleaning part 400 to supply the wafers W to the process chambers 500. In addition, the transfer module 320 may unload the wafers W from the process chambers 500 to load to the load-lock part 200.

In the back side of the transfer part 300, the cleaning part 400 and at least two process chambers 500 may be arranged side by side.

The cleaning part 400 may be located at the most side part of processing parts of the apparatus for fabricating semiconductor devices 10.

The processing parts may include the cleaning part 400 and the process chambers 500. The cleaning part 400 is illustrated as being located at the most left side end of the processing parts of the apparatus for fabricating semiconductor devices 10 in FIG. 1A.

A process of dry cleaning the wafers W may be performed in the cleaning part 400. For example, a native oxide layer, particles, or defects formed on the wafers W may be cleaned in the cleaning part 400

The cleaning part 400 may include a load/unload chamber 410 in an upper part and a cleaning chamber 420 in a lower part.

The load/unload chamber 410 may provide a space in which a wafer is received from the transfer part 300 and stacked in a wafer boat 415. The load/unload chamber 410 may be arranged at a horizontally corresponding height to the transfer chamber 310. The wafer boat 415 may descend and move from load/unload chamber 410 to the cleaning chamber 420, or ascend and move from the cleaning chamber 420 to the load/unload chamber 410, in directions shown by arrows.

The cleaning chamber 420 may perform a process of cleaning the wafers W received from the load/unload chamber 410. The load/unload chamber 410 and the cleaning part 400 may be a batch-type in which a plurality of wafers W can be processed at the same time.

A remote plasma process in which plasma is introduced from an exterior may be performed in the cleaning chamber 420. For example, the cleaning chamber 420 may receive the plasma from the external plasma supply module 600 through a plasma supply pipe 650.

The cleaning part 400 may further include a load/unload door 405 connecting the load/unload chamber 410 and the transfer chamber 310, and an inner shutter 416 connecting the load/unload chamber 410 and the cleaning chamber 420. The load/unload door 405 may be temporarily opened when the wafers W are loaded or unloaded between the load/unload chamber 410 and the transfer chamber 310. The inner shutter 416 may be temporarily opened when the wafer boat 415 ascend/descend between the load/unload chamber 410 and the cleaning chamber 420.

At least two process chambers 500 may be arranged in a row or side by side with the cleaning part 400. A process of forming a material layer on a surface of a wafer may be performed in the process chambers 500. For example, an epitaxial growth process of growing a single crystalline silicon layer on the surface of the wafer may be performed. Because the epitaxial growth process is more sensitive to an oxide material that exists on the surface of silicon compared to other processes, the oxide material may be removed just before the epitaxial growth process is performed. Ordinary deposition and/or etching processes may also be performed in the process chambers 500. When a cleaning process is performed just before the processes is performed, an improved result may be obtained even in the case of ordinary deposition and/or etching processes. The processes performed in the process chambers 500 may use plasma or heat. For example, the process chambers 500 may generate plasma from the inside.

The plasma supply module 600 may be located at the rear of the cleaning part 400. Because the plasma supply module 600 is located at the back side of the cleaning part 400, a lateral area which the apparatus for fabricating semiconductor devices 10 occupies in a clean room may be reduced. When the plasma supply module 600 is located at a side of the cleaning part 400, the lateral area which the apparatus for fabricating semiconductor devices 10 occupies in a clean room may be increased. The plasma supply module 600 may supply plasma into the cleaning chamber 420 through the plasma supply pipe 650.

The plasma supply pipe 650 may include at least two first and second branch plasma supply pipes 655a and 655b. For example, the first branch plasma supply pipe 655a may supply the plasma to an upper part of the cleaning chamber 420, and the second branch plasma supply pipe 655b may supply the plasma to a lower part of the cleaning chamber 420.

A reaction gas exhaust part 700 may be located at a front of the cleaning chamber 420. The reaction gas exhaust part 700 may be arranged below the transfer chamber 310 to be connected to the cleaning chamber 420. Accordingly, the reaction gas exhaust part 700 may exhaust gas and/or plasma in a downward direction of the apparatus for fabricating semiconductor devices 10. For example, in the event that the cleaning chamber 420 is arranged above the load/unload chamber 410, then an efficiency of space utilization may be decreased because the reaction gas exhaust part 700 cannot be arranged in the front side of the cleaning chamber 420 and below the transfer chamber 310. However, in accordance with the example embodiment, the space utilization may increase because the cleaning chamber 420 is arranged below the load/unload chamber 410, and therefore the reaction gas exhaust part 700 can be arranged in the front side of the cleaning chamber 420 and below the transfer chamber 310. The reaction gas exhaust part 700 may be connected to a service area of a basement of the clean room.

Elements 600 and 650 for supplying the plasma and the reaction gas to the cleaning chamber 420 may be arranged to face the reaction gas exhaust part 700 for exhausting the plasma and the reaction gas from the cleaning chamber 420. As shown in FIGS. 1A and 1B, both the elements 600 and 650 for supplying the plasma and the reaction gas and the reaction gas exhaust part 700 for exhausting the plasma and the reaction gas may be located in a straight line. Accordingly, the flat area of the clean room occupied by the apparatus for fabricating semiconductor devices 10 in accordance with the example embodiment may be reduced. In addition, because the apparatus for fabricating semiconductor devices 10 in accordance with the example embodiment has multiple chambers 420 and 500, two or more processes may be performed in-situ without breaking vacuum.

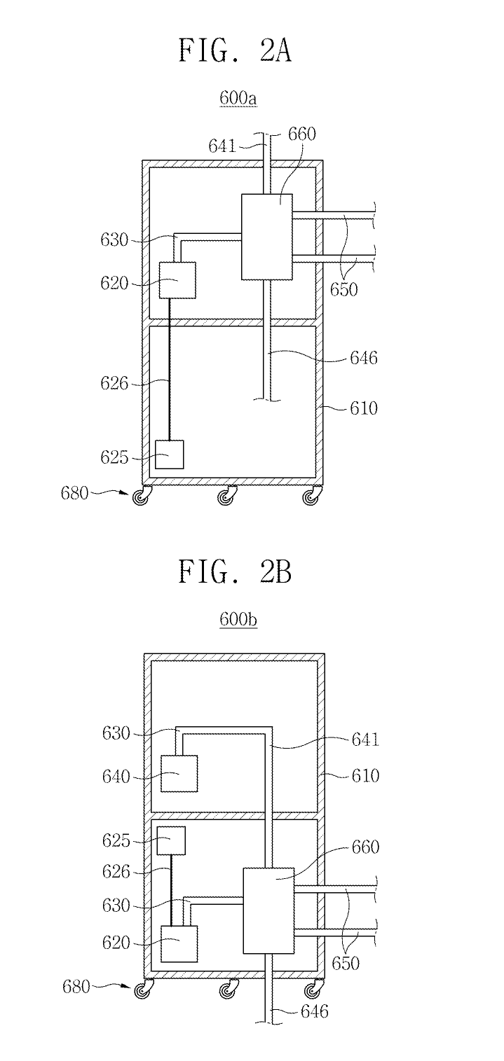

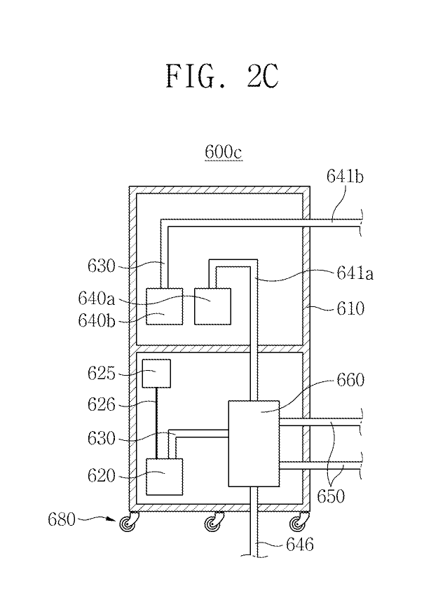

FIGS. 2A to 2C are block diagrams schematically illustrating plasma supply modules 600a to 600c of the apparatus for fabricating semiconductor devices 10 in accordance with example embodiments.

Referring to FIG. 2A, the plasma supply module 600a in accordance with an example embodiment may include a microwave applicator 620 arranged in a module frame 610, a microwave waveguide 630, a gas supply pipe 641, a gas circulating pipe 646, a plasma generator 660, and plasma supply pipes 650.

The module frame 610 may include, for example, a framework or shelves. The module frame 610 may include a stainless steel.

The microwave applicator 620 may generate microwaves. The microwave waveguide 630 may supply the microwaves generated from the microwave applicator 620 to plasma generator 660.

The gas supply pipe 641 may supply various gases, e.g., H₂, F₂, N₂, NH₃, NF₃, and NHxFy, to the plasma generator 660.

The plasma generator 660 may receive the microwaves and the gas to generate plasma. For example, the plasma generator 660 may generate plasma including a hydrogen radical (H*). The plasma generated in the plasma generator 660 may be supplied to the cleaning chamber 420 through the plasma supply pipes 650.

A gas circulating pipe 646 may transfer the gas passing through the plasma generator 660, for example, to the service area, in order to exhaust or reuse the gas. The gas circulating pipe 646 is simply illustrated in FIGS. 2A and 2B.

The plasma supply module 600a may include a microwave power supply 625. The microwave power supply 625 may supply a power to the microwave applicator 620 through a power supply line 626. For example, all elements necessary to generate microwaves may be installed in the plasma supply module 600a.

The plasma supply module 600a may further include a caster 680 arranged below the module frame 610. The caster 680 may enable the plasma supply module 600a to be easily moved when the plasma supply module 600a is separated from the cleaning part 400. Thus, a repair and/or replacement work for the plasma supply module 600a can be easily performed.

Referring to FIG. 2B, the plasma supply module 600b in accordance with an example embodiment may further include a gas tank 640. For example, the gas tank 640 for supplying a gas to the plasma generator 660 may be installed in the plasma supply module 600b. Accordingly, both of the microwave supplying part and the gas supplying part for generating plasma may be installed in the plasma supply module 600b.

Referring to FIG. 2C, the plasma supply module 600c in accordance with an example embodiment may include first and second gas tanks 640a and 640b, and first and second gas supply pipes 641a and 641b. For example, the first gas tank 640a that supplies a gas to the plasma generator 660 through the first gas supply pipe 641a, and the second gas tank 640b that directly supplies a gas to the cleaning chamber 420 through the second gas supply pipe 641b may be installed in the plasma supply module 600c. Accordingly, a plasma supplying part and cleaning gas supplying part for performing a cleaning process may be installed in the plasma supply module 600c.

In accordance with example embodiments, elements supplying plasma and/or gas to the cleaning chamber 420 may be provided in a form of a single module. Accordingly, processes of inspection, repair, maintenance, replacement, and test of the apparatus for fabricating semiconductor devices 10 may be easily performed because the modularized elements supplying plasma and/or gas can be separated and managed independently.

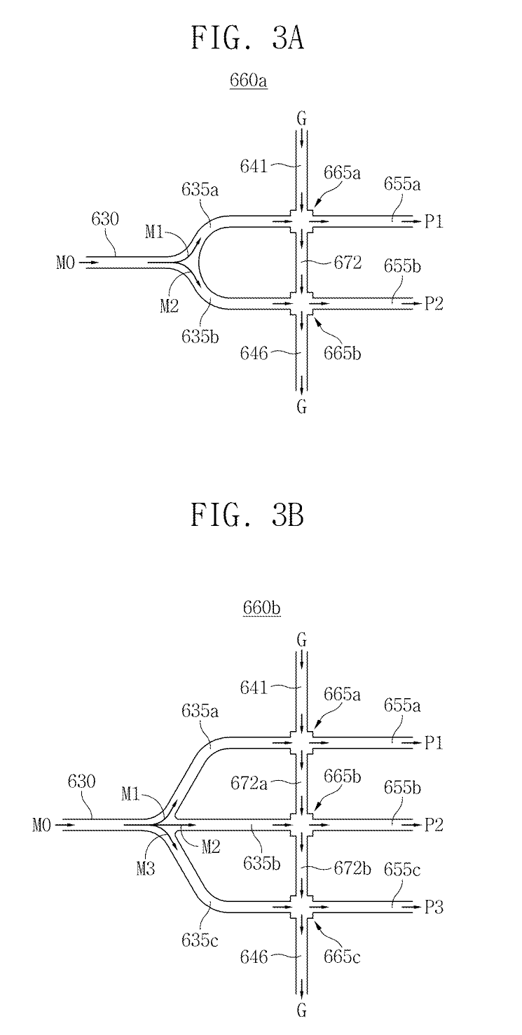

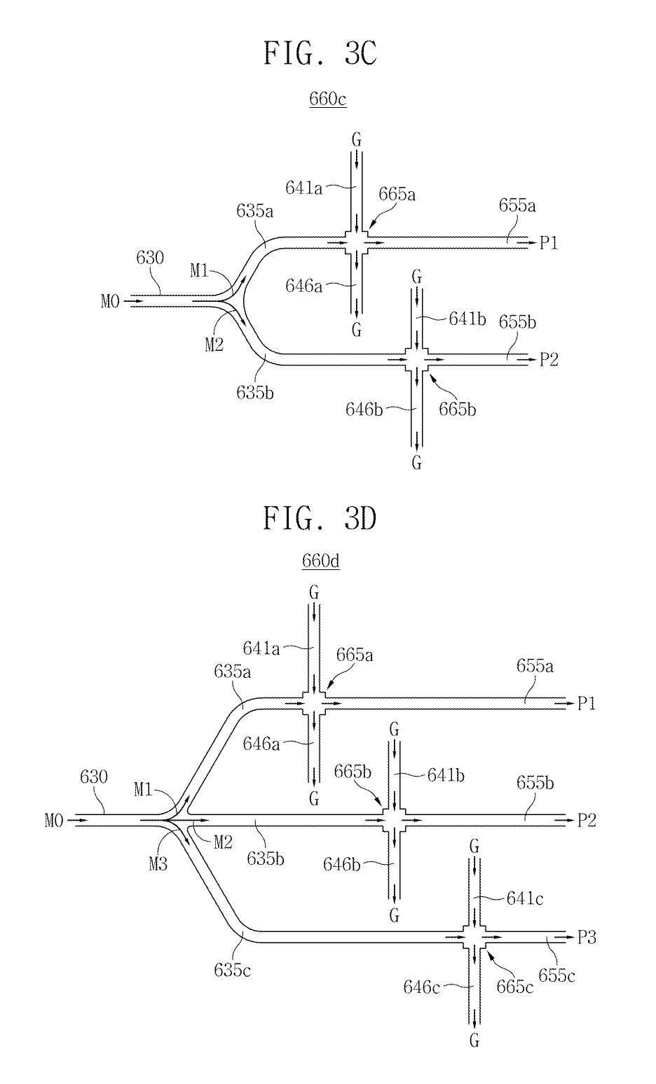

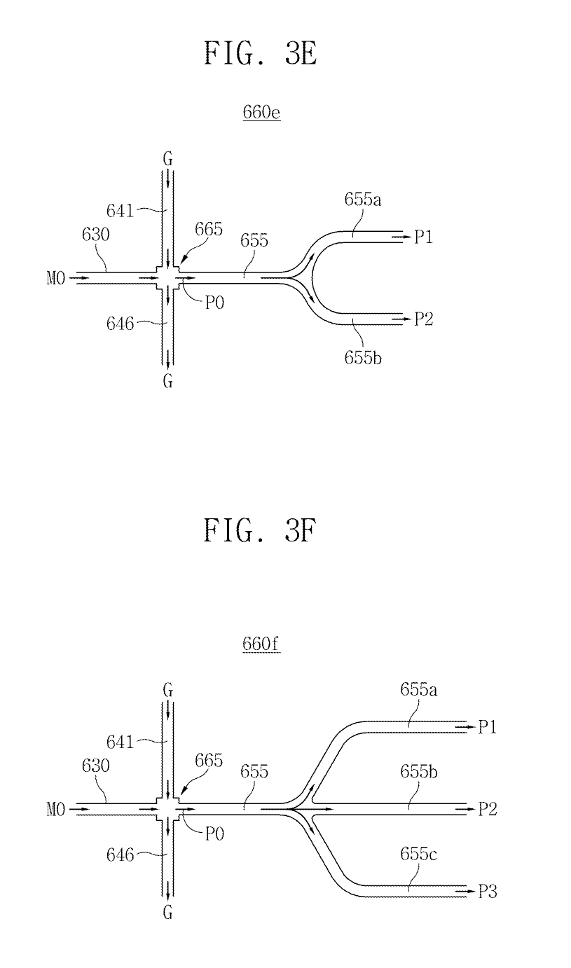

FIGS. 3A to 3F are block diagrams schematically illustrating plasma generators 660a-660f in accordance with various example embodiments.

Referring to FIG. 3A, the plasma generator 660a in accordance with an example embodiment may include divided first and second branch microwave waveguides 635a and 635b, a first unit plasma generator 665a and a second unit plasma generator 665b, and an intermediate gas pipe 672.

The first branch microwave waveguide 635a and the second branch microwave waveguide 635b may be divided from the microwave waveguide 630. The first branch microwave waveguide 635a may be connected to the first unit plasma generator 665a, and the second branch microwave waveguide 635b may be connected to the second unit plasma generator 665b. Accordingly, a main microwave M0 generated from the microwave applicator 620 may be divided to a first microwave M1 passing through the first branch microwave waveguide 635a and a second microwave M2 passing through the second branch microwave waveguide 635b.

The first unit plasma generator 665a may be connected to a first branch plasma supply pipe 655a, and the second unit plasma generator 665b may be connected to a second branch plasma supply pipe 655b. For example, a first plasma P1 generated from the first unit plasma generator 665a may be supplied to the cleaning chamber 420 through the first branch plasma supply pipe 655a, and a second plasma P2 generated from the second unit plasma generator 665b may be supplied to the cleaning chamber 420 through the second branch plasma supply pipe 655b.

The intermediate gas pipe 672 may connect the first unit plasma generator 665a and the second unit plasma generator 665b. Accordingly, a gas G passing through the first unit plasma generator 665a may be supplied to the second unit plasma generator 665b passing through the intermediate gas pipe 672. For example, the gas G may be supplied to the first unit plasma generator 665a through the gas supply pipe 641 and excited to generate the first plasma P1 by the first microwave M1 in the first unit plasma generator 665a, and the gas G passing through the first unit plasma generator 665a may be excited to generate the second plasma P2 by the second microwave M2 in the second unit plasma generator 655b. The gas G passing through the second unit plasma generator 655b may be exhausted to outside or to be circulated through the gas circulating pipe 646 for reuse.

Referring to FIG. 3B, the plasma generator 660b in accordance with an example embodiment may include first to third branch microwave waveguides 635a to 635c, first to third unit plasma generators 665a to 665c, and first to third plasma supply pipes 655a to 655c. For example, the plasma generator 660b may include at least three branch microwave waveguides 635a, 635b, and 635c, at least three unit plasma generators 665a, 665b, and 665c, and at least three branch plasma supply pipes 655a, 655b, and 655c. The main microwave M0 may be divided into first to third microwaves M1, M2, and M3 passing through the first to third branch microwave waveguides 635a to 635c. The intermediate gas pipes 672 may include a first intermediate gas pipe 672a and a second intermediate gas pipe 672b. The intermediate gas pipes 672a and 672b may connect the first to third plasma generators 665a to 665c in series. For example, the first intermediate gas pipe 672a may connect the first unit plasma generator 665a and the second unit plasma generator 665b, and the second intermediate gas pipe 672b may connect the second unit plasma generator 665b and the third unit plasma generator 665c. Accordingly, the gas G may sequentially pass through the first to third unit plasma generators 665a to 665c.

Referring to FIG. 3C, the plasma generator 660c in accordance with an example embodiment may include the first branch microwave waveguide 635a and the second branch microwave waveguide 635b, and the first unit plasma generator 665a and the second unit plasma generator 665b, the first unit plasma generator 665a may be connected to a first branch gas supply pipe 641a and a first branch gas circulating pipe 646a, and the second unit plasma generator 665b may be connected to the second branch gas supply pipe 641b and the second branch gas circulating pipe 646b. The first unit plasma generator 665a and the second unit plasma generator 665b may be arranged independently or in parallel. The first unit plasma generator 665a may be connected to the cleaning chamber 420 through the first branch plasma supply pipe 655a, and the second unit plasma generator 665b may be connected to the cleaning chamber 420 through the second branch plasma supply pipe 655b.

Referring to FIG. 3D, the plasma generator 660d in accordance with an example embodiment may include the first to third branch microwave waveguides 635a to 635c and the first to third unit plasma generators 665a to 665c, the first unit plasma generator 665a may be connected to the first branch gas supply pipe 641a and the first branch gas circulating pipe 646a, the second unit plasma generator 665b may be connected to the second branch gas supply pipe 641b and the second branch gas circulating pipe 646b, and the third unit plasma generator 665c may be connected to a third branch gas supply pipe 641c and a third branch gas circulating pipe 646c. The first unit plasma generator 665a, the second unit plasma generator 665b, and the third unit plasma generator 665c may be arranged independently or in parallel. The first unit plasma generator 665a may be connected to the cleaning chamber 420 through the first branch plasma supply pipe 655a, the second unit plasma generator 665b may be connected to the cleaning chamber 420 through the second branch plasma supply pipe 655b, and the third unit plasma generator 665c may be connected to the cleaning chamber 420 through the third branch plasma supply pipe 655c.

Referring to FIG. 3E, the plasma generator 660e in accordance with an example embodiment may include the unit plasma generator 665, the main plasma supply pipe 655, and the divided first and second branch plasma supply pipes 655a and 655b. The main plasma P0 generated from the unit plasma generator 665 may be divided into the first plasma P1 and the second plasma P2 respectively as passing through the first branch plasma supply pipe 655a and the second branch plasma supply pipe 655b, and the first plasma P1 and the second plasma P2 are supplied to the cleaning chamber 420.

Referring to FIG. 3F, the plasma generator 660f in accordance with an example embodiment may include the unit plasma generator 665, the main plasma supply pipe 655, and the divided first to third branch plasma supply pipes 655a to 655c. The main plasma P0 generated from the unit plasma generator 665 may be divided into first to third plasma P1, P2, and P3 respectively as passing through the first to third branch plasma supply pipes 655a to 655c, and the first to third plasma P1, P2, and P3 are supplied to the cleaning chamber 420.

Here, elements which are not described in FIGS. 3B to 3F may be understood with reference to FIG. 3A.

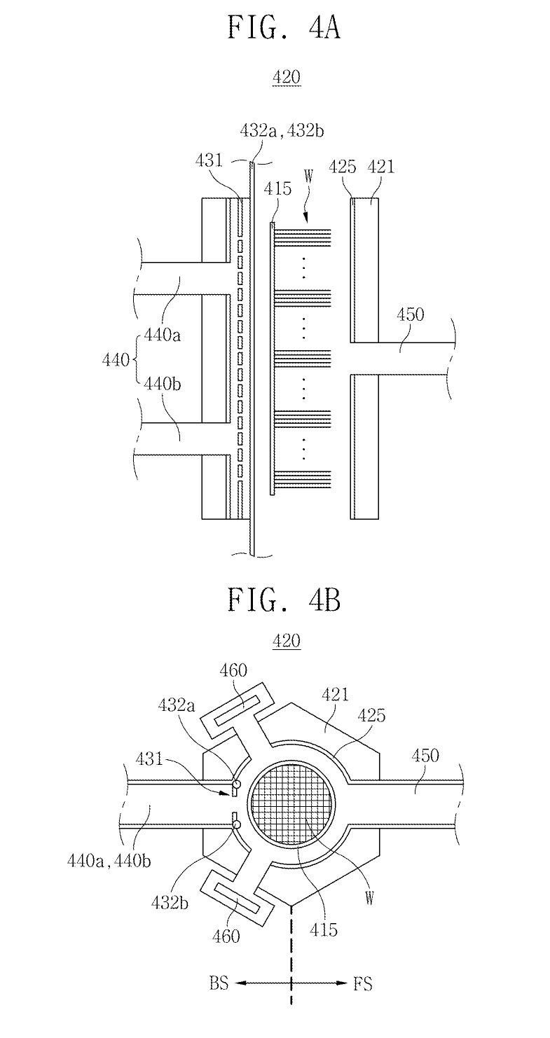

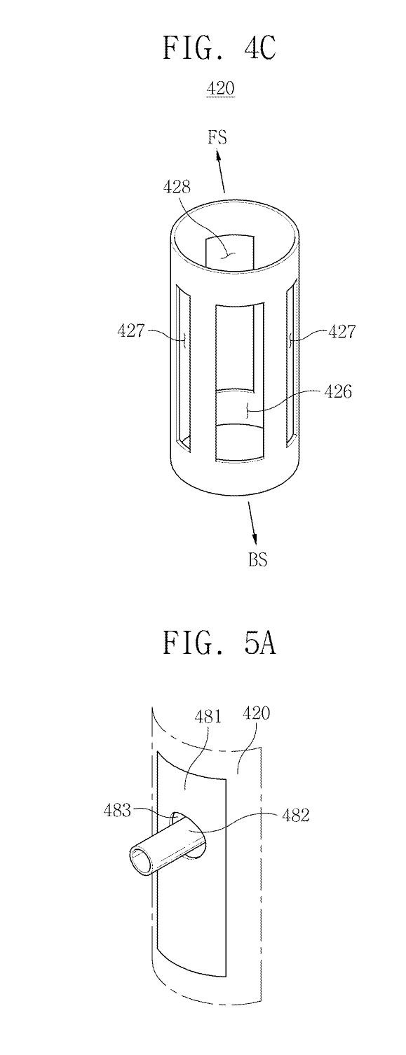

FIGS. 4A to 4C are block diagrams schematically illustrating a cleaning chamber 420 of an apparatus for fabricating semiconductor devices 10 in accordance with example embodiments. For example, FIG. 4A shows a longitudinal schematic cross-sectional view of the cleaning chamber 420, FIG. 4B is a schematic cross-sectional view of the cleaning chamber 420, and FIG. 4C is a schematic perspective view illustrating the cleaning chamber 420 in accordance with an example embodiment. FIG. 4B provides a plan cross-section of the cleaning chamber 420 so that the example embodiment can be easily understood. Some features shown in FIGS. 4A to 4C may be simplified or exaggerated so that the example embodiments can be easily understood.

Referring to FIGS. 4A and 4B, the cleaning chamber 420 may include a housing 421, an inner chamber 425, first and second shower nozzles 431, and 432a and 432b, first and second internal plasma supply pipes 440a and 440b, and an internal gas exhaust pipe 450.

The inner chamber 425 may be coupled or attached to the housing 421. The housing 421 may have a polygonal shape, and the inner chamber 425 may have a cylindrical shape. The inner chamber 425 may include an aluminum tube or a stainless metal.

The first and second internal plasma supply pipes 440a and 440b and the internal gas exhaust pipe 450 may face each other. For example, further referring to FIGS. 1A to 1B, the first and second internal plasma supply pipes 440a and 440b may be arranged in a back side (BS) of the cleaning chamber 420, and the internal gas exhaust pipe 450 may be arranged in a front side (FS) of the cleaning chamber 420.

The first and second shower nozzles 431, and 432a and 432b may be arranged in the cleaning chamber 420 in order to correspond to the first and second internal plasma supply pipes 440a and 440b. The first shower nozzle 431 may have a shape of vertical bar including a plurality of holes. The first shower nozzle 431 may uniformly distribute and supply plasma including a hydrogen radical H* into the cleaning chamber 420. The cleaning chamber 420 may include two or more second shower nozzles 432a and 432b. Referring to FIG. 4B, the second shower nozzles 432a and 432b may be arranged in parallel at both sides of the first shower nozzle 431. The second shower nozzles 432a and 432b may have a shape of vertical tube including a plurality of holes. The second shower nozzles 432a and 432b may supply an NF₃ gas into the cleaning chamber 420.

The first internal plasma supply pipe 440a may supply plasma to an upper part of the cleaning chamber 420 and the second internal plasma supply pipe 440b may supply plasma to a lower part of the cleaning chamber 420.

The internal gas exhaust pipe 450 may be arranged in a middle part of the cleaning chamber 420. The internal gas exhaust pipe 450 may exhaust a reaction gas and plasma in the cleaning chamber 420 to the gas circulating pipe 646 outside of the cleaning chamber 420.

Further referring to FIG. 4B, the cleaning chamber 420 may include lamp heaters 460 which heat the inside of the cleaning chamber 420. The lamp heaters 460 may include a halogen lamp. The lamp heaters 460 may be arranged close to the back side (BS) of the cleaning chamber 420.

Referring to FIG. 4C, the cleaning chamber 420 may include a supply window 426 arranged toward the back side (BS), lamp windows 427, and an exhaust window 428 arranged toward the front side (FS). The first and second shower nozzles 431, and 432a and 432b, and the internal plasma supply pipes 440 may be arranged and combined to the supply window 426. The lamp heaters 460 may be arranged and combined to the lamp windows 427. The internal gas exhaust pipe 450 may be arranged and combined to the exhaust window 428.

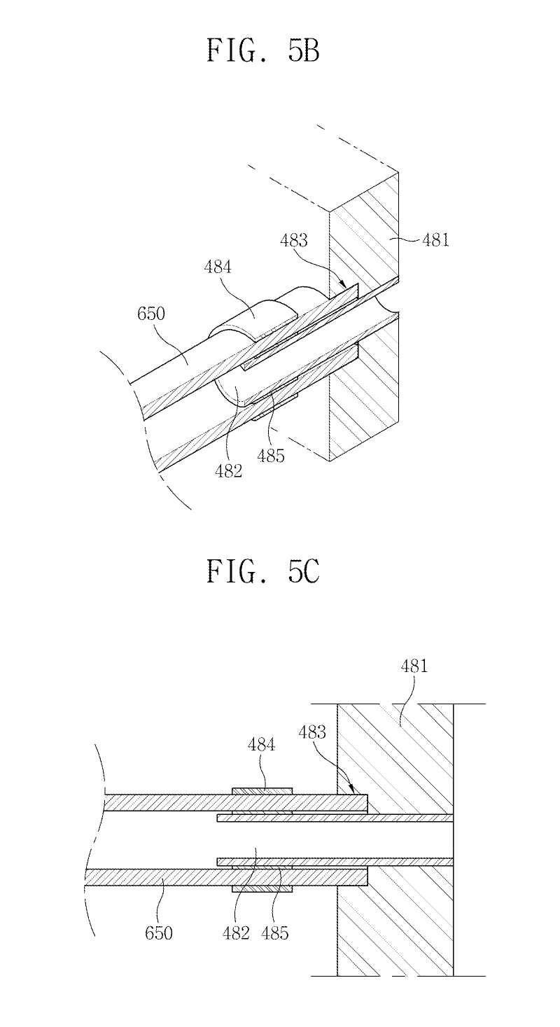

FIGS. 5A to 5C are a perspective view, a cross-sectional perspective view, and a cross-sectional view, respectively, schematically illustrating the plasma supply pipe 650 combined with the cleaning chamber 420.

Referring to FIG. 5A, the cleaning chamber 420 may include a protruding inlet part 482, and a supply window cover 481 having a concave part 483 around the inlet part 482. The supply window cover 481 may be combined with the supply window 426 of the inner chamber 425 in FIGS. 4B-4C.

Referring to FIGS. 5B and 5C, the inlet part 482 may be inserted to the inside of the plasma supply pipe 650, and the ending part of the plasma supply pipe 650 may be inserted to the concave part 483. The plasma supply pipe 650 and the inlet part 482 may be combined together by a tightening belt 484 surrounding the outside of the plasma supply pipe 650. A gasket 485 may be inserted between the plasma supply pipe 650 and the inlet part 482 to surround the outside of the inlet part 482.

According to the example embodiment, the plasma supply pipe 650 and the inlet part 482 may be combined using the cylindrical gasket 485 and tightening belt 484 without using a tightening bolt or disk-type gasket for combining. Accordingly, it is easy to combine or separate the plasma supply module 600 and the cleaning chamber 420, which saves time.

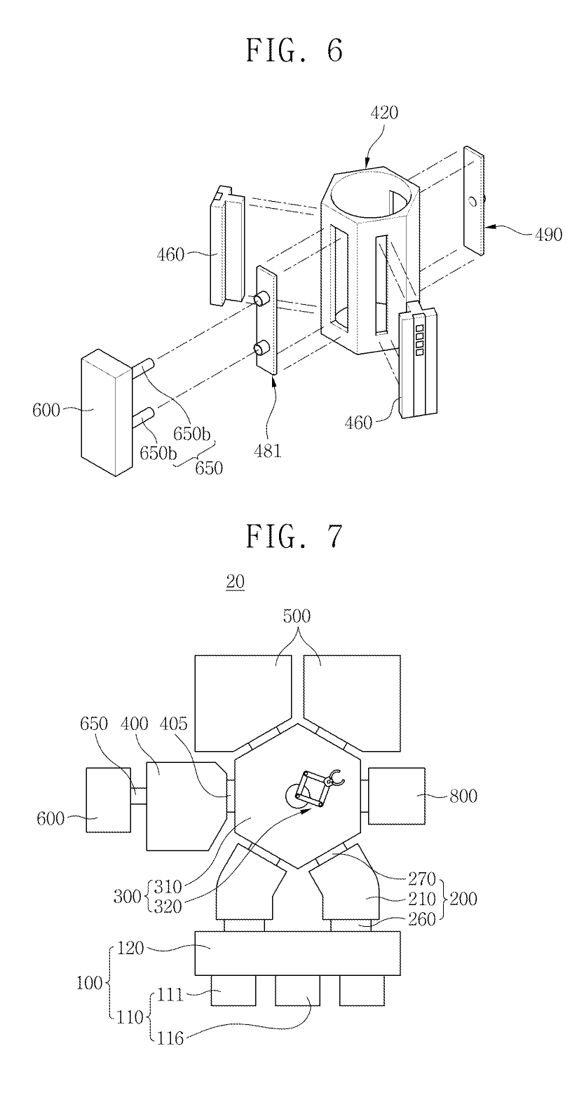

FIG. 6 is a disassembled view schematically illustrating the cleaning chamber of the apparatus for fabricating semiconductor devices 10 in accordance with an example embodiment.

Referring to FIG. 6, the plasma supply module 600, the lamp heaters 460, the first and second shower nozzles 431 and 432a and 432b, and the cleaning chamber 420 may be independently or sequentially separated at a back side of the apparatus for fabricating semiconductor devices 10.

For example, the plasma supply module 600 may be separated from the apparatus for fabricating semiconductor devices 10 by separating the plasma supply pipe 650 and the housing 421. According to the example embodiment, the plasma supply module 600 may be easily combined to and separated from the apparatus for fabricating semiconductor devices 10 or the cleaning chamber 420 using the tightening belt 484, without using a complex means for tightening such as a tightening bolt.

After the plasma supply module 600 is separated, the lamp heaters 460 may be separated from the housing 421. Because the lamp heaters 460 are arranged in the back side of the apparatus for fabricating semiconductor devices 10 or the cleaning chamber 420, the lamp heaters 460 may be separated without separating the cleaning chamber 420 from the apparatus for fabricating semiconductor devices 10.

After the lamp heaters 460 are separated, the cleaning chamber 420 may be separated from the cleaning part 400. Alternatively, the cleaning chamber 420 may be separated from the cleaning part 400 without separating the lamp heaters 460.

An exhaust window cover 490 arranged to face the plasma supply pipe 650 may be separated.

Accordingly, when a part needs to be repaired or replaced in the apparatus for fabricating semiconductor devices 10, equipment maintenance and/or equipment replacement may be easily performed because the part to be repaired or replaced can be easily separated.

FIG. 7 is a block diagram schematically illustrating an apparatus for fabricating semiconductor devices 20 in accordance with an example embodiment.

Referring to FIG. 7, the apparatus for fabricating semiconductor devices 20 in accordance with an example embodiment may include a stock part 100, a load-lock part 200, a cleaning part 400, and process chambers 500 arranged in a circular or radial shape around a transfer part 300. The apparatus for fabricating semiconductor devices 20 may further include a standby chamber 800. Processed wafers may be temporarily placed in the standby chamber. For example, the processed wafers may undergo a cooling process in the standby chamber 800. Other elements, configurations and functions of this embodiment may be understood with reference to the foregoing drawings and descriptions.

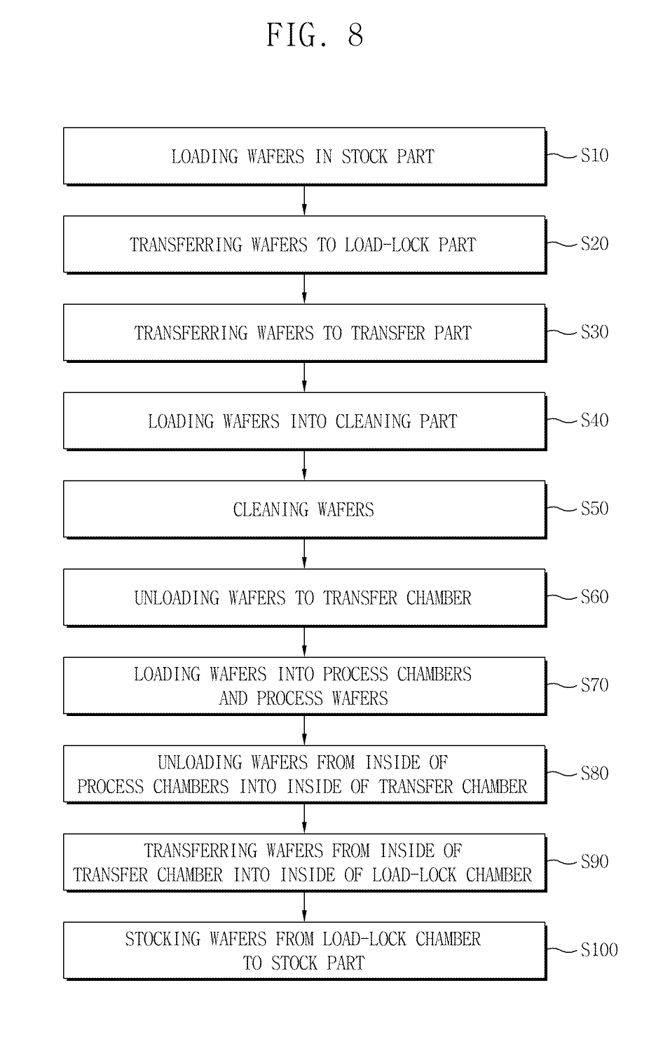

FIG. 8 is a flowchart describing processes of manufacturing a semiconductor device using the apparatus for fabricating semiconductor devices 10 in accordance with an example embodiment.

Referring to FIGS. 1A, 1B, 7, and 8, a method of manufacturing a semiconductor device in accordance with an example embodiment may include loading the wafers W into the stock part 100 (S10). For example, the loading process may include loading a wafer carrier in which the wafers W are stacked onto the inlet stock table 111 and move the inlet stock table 111 to the stock rack 120 (S20).

Next, the method of manufacturing a semiconductor device in accordance with an example embodiment may include transferring the wafers W to the load-lock part 200. For example, the transfer process may include opening the outer door 260, transferring the wafers W located on the stock rack 120 into the load-lock chamber 210, and closing the outer door 260.

Next, the method of manufacturing a semiconductor device in accordance with an example embodiment may include transferring the wafers W to the transfer part 300 (S30). For example, the transfer process may include evacuating the inside of the load-lock chamber 210, opening the inner door 270, and bringing the wafers W into the transfer chamber 310 using the transfer module 320.

Next, the method of manufacturing a semiconductor device in accordance with an example embodiment may include loading the wafers W into the cleaning part 400 (S40). For example, the loading process may include opening the load/unload door 405, loading the wafers W in the wafer boat 415 located in the load/unload chamber 410, closing the load/unload door 405, descending the wafer boat 415 to the inside of the cleaning chamber 420, and closing the inner shutter 416.

Next, the method of manufacturing a semiconductor device in accordance with an example embodiment may include cleaning the wafers W (S50). The cleaning process may include supplying plasma in the cleaning chamber 420 and cleaning the wafers W.

Next, the method of manufacturing a semiconductor device in accordance with an example embodiment may include unloading the wafers W to the transfer chamber 310 (S60). For example, the unloading process may include exhausting plasma in the cleaning chamber 420 using the reaction gas exhaust part 700, opening the inner shutter 416, and ascending the wafer boat 415 to the load/unload chamber 410, opening the load/unload door 405, and unloading the wafers W to the transfer chamber 310 using the transfer module 320.

Next, the method of manufacturing a semiconductor device in accordance with an example embodiment may include loading the wafers W to the inside of the process chambers 500 and processing the wafers W (S70). For example, the loading process may include loading the wafers W to the inside of the process chambers 500 from the transfer chamber 310 using the transfer module 320. The processing of the wafers W may include forming a material layer on the wafers W. For example, the processing of the wafers W may include performing an epitaxial growth process on the wafers W to form a single crystalline silicon layer.

Next, the method of manufacturing a semiconductor device in accordance with an example embodiment may include unloading the wafers W from the process chambers 500 into the transfer chamber 310 (S80). For example, the unloading process may include unloading the wafers W from the process chambers 500 to the transfer chamber 310 using the transfer module 320.

Next, the method of manufacturing a semiconductor device in accordance with an example embodiment may include transferring the wafers W from the transfer chamber 310 to the inside of the load-lock chamber 210 (S90). For example, the transfer process may include opening the inner door 270, transferring the wafers W to the inside of the load-lock chamber 210 using the transfer module 320, and closing the inner door 270.

Next, the method of manufacturing a semiconductor device in accordance with an example embodiment may include loading the wafers W from load-lock chamber 210 into the stock part 100 (S 100). The loading process may include adjusting the internal pressure of the load-lock chamber 210 to be the atmosphere pressure, opening the outer door 260, loading the wafers W in the load-lock chamber 210 into the stock part 100.

According to the method of manufacturing a semiconductor device in accordance with example embodiments, the processes of cleaning the wafers W and forming the material layer on the wafers W may be performed in-situ without breaking vacuum. Because the time for manufacturing a semiconductor device is reduced, the productivity may increase. Because the processes of cleaning the wafers W and forming the material layer on the wafers W may be performed in-situ, the formation of unnecessary defects such as a native oxide layer on the wafers W may be prevented during the processes of cleaning the wafers W and forming the material layer on the wafers W. Accordingly, the yield of the process of manufacturing a semiconductor process may increase.

Because the semiconductor manufacturing apparatus in accordance with various example embodiments has multiple chambers, various processes may be performed in series. Accordingly, time spent for manufacturing a semiconductor device may be saved.

Because the semiconductor manufacturing apparatus in accordance with various example embodiments has a plasma supply module at a back side of the apparatus, the apparatus may occupy a relatively small space of the clean room and substantial additional space for inspecting and maintaining the apparatus may not be required. Therefore, a dead space area may decrease, and the density of apparatuses in the clean room may increase.

Because the semiconductor manufacturing apparatus in accordance with various example embodiments provides elements for supplying plasma in the form of a module, the apparatus may be easily separated, combined, repaired, maintained, and replaced.

Because the semiconductor manufacturing apparatus in accordance with various example embodiments does not need a horizontal space for elements exhausting a reaction gas, the density of the apparatus in the clean room may increase.

Because the semiconductor manufacturing apparatus in accordance with various example embodiments has a part for supplying plasma and/or gas and a part for exhausting plasma and/or gas which are facing each other, efficiency of cleaning and/or processing may increase.

The foregoing is illustrative of example embodiments and should not to be construed as being limited to the example embodiments set forth herein. Although a few embodiments have been described, those skilled in the art will readily appreciate that various modifications are possible without materially departing from the principles, spirit, and scope of the inventive concepts defined by the following claims and their equivalents. In the claims, means-plus-function clauses are intended to cover the structures described herein as performing the recited function.

What is claimed is:

1. An apparatus for fabricating semiconductor devices, comprising:
a load-lock part arranged adjacent to a front side of a transfer part;
a cleaning part and at least two process chambers arranged side by side adjacent to a back side of the transfer part;
a plasma supply module arranged at a back side of the cleaning part, the plasma supply module configured to supply plasma to the cleaning part; and
a reaction gas exhaust part coupled to the cleaning part and arranged below the transfer part, the reaction gas exhaust part configured to exhaust a reaction gas from the cleaning part.

2. The apparatus for fabricating semiconductor devices of claim 1, wherein the cleaning part comprises:
a load/unload chamber arranged at an upper part thereof;
a cleaning chamber arranged at a lower part thereof; and
a wafer boat configured to ascend/descend between the load/unload chamber and the cleaning chamber.

3. The apparatus for fabricating semiconductor devices of claim 2, wherein the cleaning chamber comprises:
an exhaust window at a front side, the exhaust window coupled with the reaction gas exhaust part; and
a supply window configured to face the exhaust window, the supply window configured to supply the plasma therethrough.

4. The apparatus for fabricating semiconductor devices of claim 3, wherein the cleaning chamber further comprises:
an exhaust window cover coupled with the exhaust window, the exhaust window cover including an internal gas exhaust pipe, the internal gas exhaust pipe coupled with the reaction gas exhaust part.

5. The apparatus for fabricating semiconductor devices of claim 3, wherein the cleaning chamber further comprises:
a supply window cover coupled with the supply window, the supply window cover including a first internal plasma supply pipe at an upper part of the cleaning chamber and a second internal plasma supply pipe at a lower part of the cleaning chamber.

6. The apparatus for fabricating semiconductor devices of claim 5, wherein the supply window cover comprises:
a protruding inlet part; and
a concave part configured to cover the inlet part.

7. The apparatus for fabricating semiconductor devices of claim 3, wherein the cleaning chamber further comprises:
a lamp window located at a back side; and
a lamp coupled with the lamp window.

8. The apparatus for fabricating semiconductor devices of claim 3, wherein the cleaning chamber comprises:
a first shower nozzle aligned with the supply window and configured to supply plasma; and
a second shower nozzle vertically parallel to the first shower nozzle and configured to supply a gas.

9. The apparatus for fabricating semiconductor devices of claim 1, wherein the plasma supply module comprises:
a microwave applicator configured to generate microwaves;
a plasma generator configured to receive the microwaves to generate plasma;
a microwave waveguide configured to transfer the microwaves generated from the microwave applicator to the plasma generator;
a gas supply pipe configured to supply a gas to the plasma generator; and
a gas circulating pipe configured to exhaust the gas from the plasma generator.

10. The apparatus for fabricating semiconductor devices of claim 9, wherein the plasma supply module further comprises:
a microwave power supply configured to supply a power to the microwave applicator; and
a gas tank configured to supply the gas to the gas supply pipe.

11. The apparatus for fabricating semiconductor devices of claim 9,
wherein the plasma generator includes a first unit plasma generator and a second unit plasma generator;
wherein the microwave waveguide includes a first branch microwave waveguide connected to the first unit plasma generator, and a second branch microwave waveguide connected to the second unit plasma generator; and
wherein the gas supply pipe supplies the gas to the first unit plasma generator, and the gas circulating pipe exhausts the gas from the second unit plasma generator.

12. The apparatus for fabricating semiconductor devices of claim 11, wherein the plasma supply module further comprises
an intermediate gas pipe configured to supply the gas generated from the first unit plasma generator to the second unit plasma generator.

13. The apparatus for fabricating semiconductor devices of claim 9, wherein the plasma supply module further comprises:
a module frame; and
casters at a bottom of the module frame, the casters configured to move the module frame.

14. The apparatus for fabricating semiconductor devices of claim 1, further comprising:
a stock part arranged at a front side of the load-lock part,
wherein the load-lock part includes,
at least two load-lock chambers;
outer doors between the load-lock chambers and the stock part; and
inner doors between the load-lock chambers and the transfer part.

15. An apparatus for fabricating semiconductor devices, comprising:
a load-lock chamber arranged at a front side of a transfer chamber;
a stock table arranged at a front side of the load-lock chamber;
a cleaning part and a process chamber arranged at a back side of the transfer chamber, wherein the cleaning part includes a load/unload chamber at an upper part thereof and a cleaning chamber at a lower part thereof;
a plasma supply module arranged at a back side of the cleaning chamber;
first and second plasma supply pipes configured to supply plasma from the plasma supply module to the cleaning chamber, wherein the first plasma supply pipe supplies the plasma to an upper part of the cleaning chamber, and the second plasma supply pipe supplies the plasma to a lower part of the cleaning chamber; and
a reaction gas exhaust part arranged at a front side of the cleaning part.

16. A semiconductor processing apparatus, comprising:
a cleaning part and at least one processing part arranged side-by-side at a back side of a transfer part;
plasma supply elements coupled to the cleaning part at a back side of the cleaning part; and
a reaction gas exhaust part coupled to the cleaning part at a front side of the cleaning part, the reaction gas exhaust part being vertically at a different level from the transfer part and configured to exhaust a reaction gas.

17. The semiconductor processing apparatus of claim 16, wherein the transfer part overlaps the reaction gas exhaust part in a plan view.

18. The semiconductor processing apparatus of claim 16, wherein the plasma supply elements are configured to be integrated into a module.

19. The semiconductor processing apparatus of claim 16, further comprising:
a standby chamber configured to at least one of temporarily store a processed semiconductor wafer from the cleaning part and cool the processed semiconductor wafer from the at least one processing part.

20. The semiconductor processing apparatus of claim 16, wherein the cleaning part and the at least one processing part are configured to perform processes in-situ, the cleaning part configured to at least partially remove a native oxide and the at least one processing part configured to perform processes other than removing a native oxide.
